(19) United States
(12) Patent Application Publication
(10) Pub. No.: US 2008/0055618 A1
(43) Pub. Date: Mar. 6, 2008

(54) Interpolation table with logarithmically distributed entries

(75) Inventors: Calvin L. Simmons, Bountiful, UT (US); Tom P. Skowyra, Salt Lake City, UT (US); Bret D. Winkler, South Jordan, UT (US); Cameron Farmer, Herriman, UT (US); Allen H. Tanner, Sandy, UT (US)

Correspondence Address: THORPE NORTH & WESTERN, LLP., 8180 SOUTH 700 EAST, SUITE 350, SANDY, UT, 84070, US

(73) Assignee: Evans & Sutherland Computer Corporation

(21) Appl. No.: 11/514,569

(22) Filed: Aug. 31, 2006

(51) Int. Cl. G03F 3/08

(52) U.S. Cl. 358/1.9; 358/519

(57) ABSTRACT

A system and method for correcting pixel intensities for output on a video display is disclosed. In one embodiment, the method includes the operation of generating an interpolation table having a plurality of interpolation segment endpoints spaced over a transfer function correction curve. The plurality of interpolation segment end points are distributed logarithmically over the transfer function correction curve to increase a number of correction points along a curved portion of the transfer function correction curve without substantially increasing a total number of correction points over the entire curve. Correction values for a graphic display can be determined by interpolating between the logarithmically distributed interpolation segment endpoints.

### FIELD OF THE INVENTION

The present invention relates generally to video display systems and output sources and, more particularly, the present invention relates to correcting display and output features using transfer functions to correct for intensity.

### BACKGROUND

Color is perceived as a result of a physiological perception to stimulus. The perception depends on several factors such as material properties, conditions of the observer, characteristics of the visual system, and neural processes. The stimulus is the visible portion of the electromagnetic spectrum that contacts the eyes of the observer. The attributes of color that are perceived when it is observed are hue, saturation, and intensity. The hue is defined as the actual color perceived by the individual, such as red, purple, green, etc. The saturation is the colorfulness of an area judged in proportion to its brightness. In other words, it is the purity of intensity of a specific hue. A highly saturated hue has a vivid, intense color. A less saturated hue appears more muted and gray. With no saturation at all, the hue becomes a shade of gray. Intensity is the brightness of an area judged relative to the brightness of a similarly illuminated area that appears to be white or highly transmitting.

Color can be produced by combining or mixing basic colors, typically referred to as primary colors. Red, green, and blue (RGB) can be combined or mixed to produce any color within a predefined color gamut. Cyan, magenta, yellow, and black (CMYK) can also be combined or mixed to produce colors within a slightly different color gamut than that of the RBG gamut.

The color gamut is the subset of colors which can be accurately represented in a given circumstance, such as within a given color space or by a certain output device. RGB color space is typically defined by a Cartesian cube represented by the three additive primaries of red, green and blue, as shown in FIG. 1. The RGB color space is not a uniform color space and is not correlated with the human visual perception. In other words, it is not linear with the visual perception. When certain colors cannot be displayed within a particular color model, those colors are said to be out of gamut. For example, pure red which is contained in the RGB color model gamut is out of gamut in the CMYK model.

Different kinds of technologies are used to produce colors on various kinds of video display systems. Historically, cathode ray tubes (CRT) have been used for video display. CRT technology uses electron guns directed onto a phosphor coated screen. When electrons contact the screen it causes the phosphor to produce light. Higher energy electrons produce more intense light. Color television is produced by using three electron guns, configured to illuminate a green phosphor, a blue phosphor, and a red phosphor respectively. The phosphor coatings are precisely located on a screen, with the red, green, and blue phosphor dots located near enough to appear to the human visual system as a single dot. The RGB intensities can then be varied to produce a range of colors within the RGB color gamut. The number of different colors that can be produced is dependent upon the size of steps that the red, green, and blue phosphors can be adjusted in intensity.

In a digital system, the intensity step size is directly related to a number of bits of resolution accorded to each color. For example, most modern digital video systems working in the RGB color gamut assign 8 bits to the red, green, and blue color designations. For every pixel, an eight bit number associated with its intensity is typically stored in a digital memory. An eight bit number allows 2⁸, or 256 different shades to be represented by each color. In the RGB cube of FIG. 1, blue could be defined in an 8 bit scheme as (0, 0, 256), with green and red defined respectively as (0,256,0) and (256,0,0), and with white as (256,256,256). The hue and saturation of a color can be changed by adjusting any of the three variables. This allows 2²⁴, or 256*256*256 different colors to be displayed in an eight bit system, equivalent to over 16 million colors.

A device which is able to reproduce the entire visible color space is somewhat of a holy grail in the engineering of color displays and printing processes. Complexity has historically limited display devices and printing processes to a narrow gamut of colors. For example, film used in movies has a larger color gamut than a standard definition analog television. Part of the draw of attending a movie in a theater is the lifelike presentation made possible by the relatively larger color gamut of the film medium.

Over the last several years, a revolution in video display technology has occurred. A wide variety of new types of video display technology have been successfully commercialized. Video displays can be purchased using digital micro mirror technology, liquid crystal (LCD) displays, LCD projection displays, liquid crystal on silicon (LCOS) displays, and grating light valve (GLV) displays, to name a few. The new technology has enabled an increased resolution in video displays, with 10 times more pixels displayed in a high definition than a standard definition display. Even higher definition displays are on the horizon, with full motion video capable of being shown in 32 megapixel displays.

Larger color gamuts are also possible, with new display technology taking advantage of lasers, light emitting devices, and other sources of light that allow for a larger gamut for showing a wider variety of colors. For example, new digital projection systems used in theaters can now produce more colors than film is capable of producing. With the increased screen resolutions and color gamuts, an increase in the intensity step size resolution can allow an exponential increase in the number of colors that can be displayed. Increasing intensity step size resolution to a 16 bit system for each of three colors allows 2⁴⁸ different colors to be presented, enabling over 280 trillion possible colors to be displayed. Such a display would enable the human visual system to perceive the full range of colors within the predefined gamut.

Increasing the intensity step size resolution to ten bit, twelve bit, sixteen bit, or greater is more complex, however, than merely storing larger numbers for each pixel. Entire display subsystems that have been successfully implemented for eight bit systems have to be redesigned to take full advantage of the greater resolution.

For example, pixel intensities in a CRT display are typically corrected to offset non-linear effects in an electron gun. An actual plot of a typical electron gun output 204 as compared to intensity is shown in FIG. 2. Doubling a voltage on an electron gun does not double the intensity of the phosphor. For example, the relationship between the voltage input and light output of a typical CRT can be approximated by a nonlinear curve using the equation L=(V+α)^{γ}, where L is luminosity (intensity) of the light output of a pixel in a display, v is voltage of an electron gun, α is a black-level offset, and γ is the exponential constant that causes the non-linearity.

To provide a more linear output for CRT television displays, the voltage output has historically been corrected based on the inverse of the CRT gamma curve. An inverted, so called gamma correction curve 208, is shown in FIG. 2. The curve is shaped to offset the non-linearity of the electron gun. For a CRT with a gamma of 2.2, the gamma correction curve is implemented with an exponential curve of 1/2.2.

Implementing a correction to the voltages supplied to the electron guns has historically been achieved using a lookup table. For an eight bit system, the lookup table consists of 255 entries, one for each level of intensity. Each entry represents the amount of correction necessary for that intensity based on the gamma correction curve. When a CRT is instructed by an input signal to produce a pixel having a color (32, 241, 64), three different lookup tables, one for red, green, and blue respectively, can be used to adjust the voltage at these intensities to provide the correct output at the display screen.

Other types of display devices, such as LCD, DMD, and LCOS have been designed to operate in a similar fashion to the CRT display. Although they may operate with different linearity curves, each type of display typically involves some non-linear relationship between pixel intensity and the voltage or code used to produce the signal. Thus, a gamma correction type curve, more broadly referred to as a transfer function correction curve, is often used to compensate for the non-linearities.

A modern, high definition display device may operate with a 16 bit intensity step size resolution. Such a resolution would require a lookup table comprised of 2¹⁶, or over 65,000 entries for each color. High definition displays typically project a frame comprising at least 1080 pixels by 1920 pixels, or over 2 million pixels, at a rate of at least 30 frames per second. Accordingly, each second there are potentially over 60 million different pixels displayed.

Further, many of today's new display types include thousands or millions of projecting devices, such as mirrors used in a digital micromirror device or LCOS type display, or ribbons in a grating light valve (GLV) type display. Each of the mirrors or ribbons may require individual correction curves. It may not be feasible to store the data for 65,000 sixteen bit entries in a lookup table for at least three colors for each of 4,000 ribbons in an ultra-high resolution GLV display or for millions of individual mirrors in a digital micromirror device.

### SUMMARY

A system and method for correcting pixel intensities for output on a video display is disclosed. In one embodiment, the method includes the operation of generating an interpolation table having a plurality of interpolation segment endpoints spaced over a transfer function correction curve. The plurality of interpolation segment end points are distributed logarithmically over the transfer function correction curve to increase a number of correction points along a curved portion of the transfer function correction curve without substantially increasing a total number of correction points over the entire curve. Correction values for a graphic display can be determined by interpolating between the logarithmically distributed interpolation segment endpoints.

### BRIEF DESCRIPTION OF THE DRAWINGS

Additional features and advantages of the invention will be apparent from the detailed description which follows, taken in conjunction with the accompanying drawings, which together illustrate, by way of example, features of the invention; and, wherein:

FIG. 1 is a diagram of RGB color space defined by a Cartesian cube;

FIG. 2 is a diagram of a typical gamma curve for a cathode ray tube and the inverse gamma correction curve;

FIG. 3 is a diagram of a transfer function correction curve showing straight line approximations;

FIG. 4 is flow chart depicting a method for correcting pixel intensities for output on a video display in accordance with an embodiment of the present invention;

FIG. 5 is a diagram of a transfer function correction curve divided into a plurality of logarithmically distributed levels in accordance with an embodiment of the present invention;

FIG. 6 is a diagram of a transfer function correction curve having plurality of interpolation segment endpoints 604 distributed logarithmically along the curve in accordance with an embodiment of the present invention; and

FIG. 7a is an illustration of an implementation of a system for correcting pixel intensities for output on a video display that involves logarithmically distributing interpolation table endpoints along a transfer function correction curve in accordance with an embodiment of the present invention.

FIG. 7b is a continuation of the illustration in FIG. 7a.

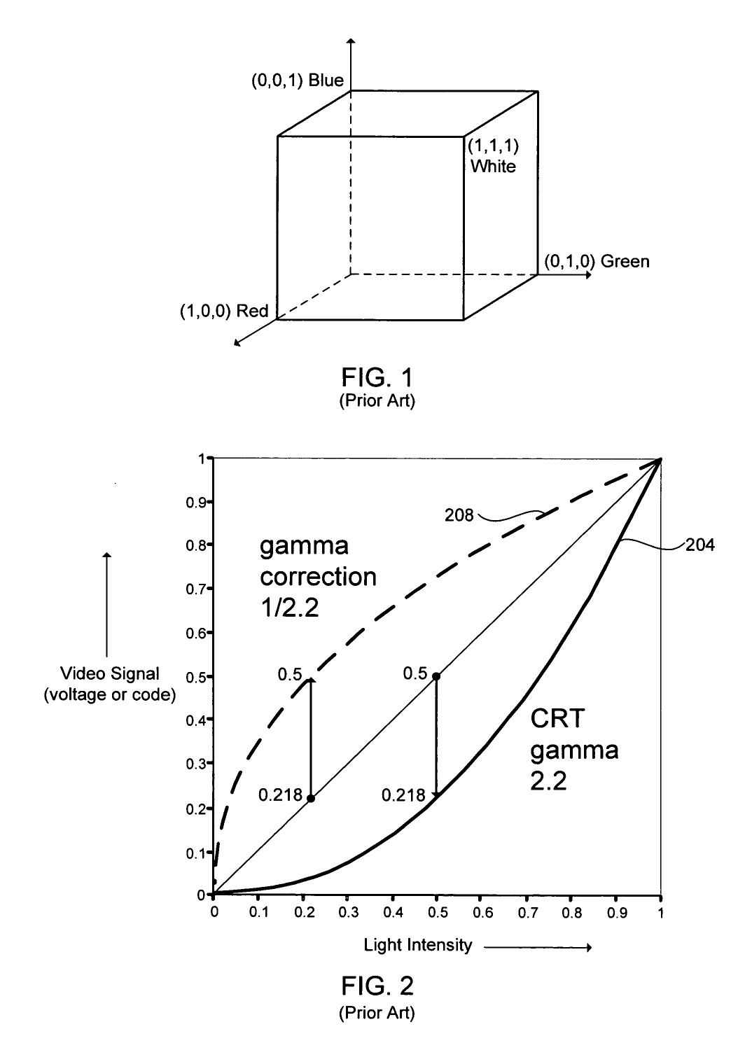

Reference will now be made to the exemplary embodiments illustrated, and specific language will be used herein to describe the same. It will nevertheless be understood that no limitation of the scope of the invention is thereby intended.

### DETAILED DESCRIPTION OF EXAMPLE EMBODIMENT(S)

In one embodiment of the present invention, an interpolation table can be implemented in place of a lookup table. Instead of storing a correction value for each pixel intensity, as is done in a lookup table, a correction curve can be divided into a series of segments 508, as shown in the transfer function correction curve 504 in FIG. 5. An interpolation table includes a plurality of interpolation segment endpoints. Each of the interpolation table entries can be identified as an endpoint (or starting point) for a segment along the curve.

Depending on the desired resolution, each curve segment 508 can represent correction values for tens or hundreds of pixel intensities. A second input can include a proportion value. The proportion value can represent a distance through the segment. The proportion value can then be used to estimate a location along the segment curve between the two interpolation table entries (endpoints). The use of an interpolation table substantially reduces the number of stored entries used to obtain a substantially accurate representation of a curve.

However, both the shape of the curve and the resolution of the intensity step size can limit the accuracy of an interpolation table. As an exponential curve approaches an asymptotical limit, the amount of curvature can significantly increase. The increased curvature can reduce the accuracy of an interpolation table for straight line approximations near the increased curvature. Reducing the size of the straight line approximation (increasing the number of interpolation segments) can increase the accuracy. However, zooming in on an asymptotic type curve to display the curve in greater detail can emphasize the amount of curvature as the curve gets ever closer to its asymptotical limit.

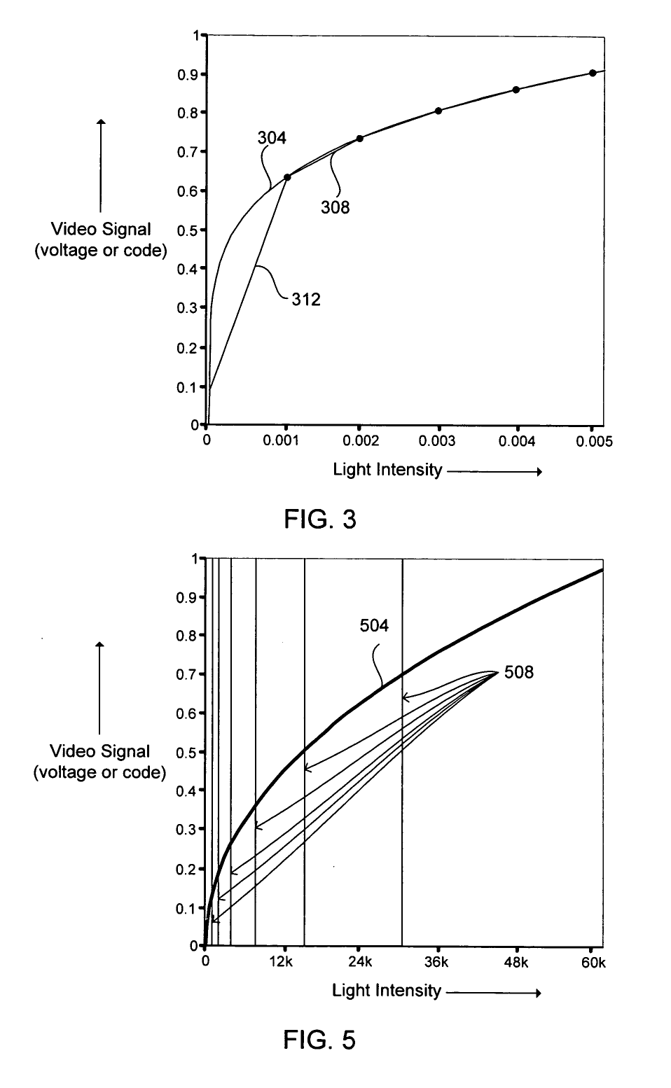

For example, a transfer function correction curve 304 is shown in FIG. 3. Straight line approximations 308 having a length of 0.001 are also shown. As the curve approaches zero, the amount of curvature, or slope, of the line approaches infinity. Zooming in on the curve only increases the amount of curvature or slope. As can be seen, the last straight line approximation 312 has a significant discrepancy from the actual curve.

Additionally, adding enough interpolation segment endpoints in a table to provide reasonably accurate straight line approximations near an asymptote or other large curvatures having a large amount of slope can be a waste of memory for approximations of straighter areas of the curve having a smaller amount of slope, as seen on the right side of FIG. 3. In one embodiment, the present invention provides a solution to this problem by distributing the interpolation segment endpoints along the curve logarithmically. Logarithmic distribution of interpolation endpoints allows an interpolation table to be used instead of the vastly larger lookup tables, while minimizing error near asymptotes and other highly curved areas and reducing the number of points used in less curved portions of the overall correction curve.

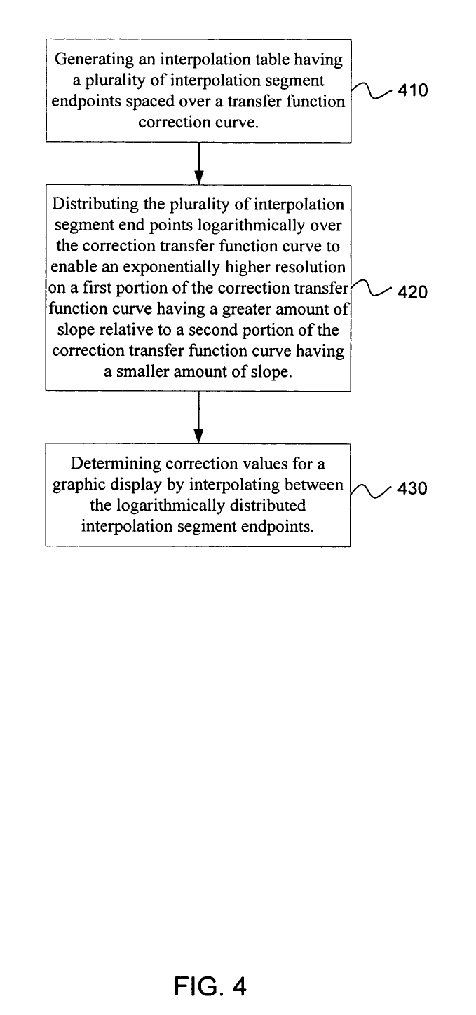

In one embodiment, a method for correcting pixel intensities for output on a video display is depicted in the flow chart in FIG. 4. The method includes the operation of generating an interpolation table having a plurality of interpolation segment endpoints spaced over a transfer function correction curve, as shown in block 410. The number of interpolation segment endpoints in the interpolation table is related to the desired accuracy of the approximations made between the endpoints.

An additional operation provides distributing the plurality of interpolation segment end points logarithmically over the correction transfer function curve to enable a higher resolution on a first portion of the correction transfer function curve having a greater amount of slope relative to a second portion of the correction transfer function curve having a smaller amount of slope, as shown in block 420. The resolution on the first portion can be exponentially higher than the resolution on the second portion of the curve due to the logarithmic distribution of the interpolation segment endpoints.

Another operation includes determining correction values for a graphic display by interpolating between the logarithmically distributed interpolation segment endpoints, as shown in block 430. As previously stated, an additional input value can include a proportion value that can represent a distance through the segment. The proportion value can then be used to estimate a location along the segment curve between the two interpolation table entries (endpoints). In one embodiment, an interpolation table can include two different types of entries, the interpolation segment endpoints representing locations along the correction curve and segment offset values associated with each of the segment endpoints. The segment offset values can represent a distance between two interpolation segment endpoints. The proportion value can then be multiplied by the segment offset value to provide a relative offset that is a substantially accurate interpolation between two segment endpoints for a specific pixel intensity value.

The interpolation segment endpoints can be logarithmically distributed along the correction curve using a variety of mathematical or graphical techniques. In one embodiment, a desired correction curve similar to those shown in FIGS. 2 and 3, can be divided into 2^{N} levels, wherein N is the number of bits of accuracy of a pixel intensity value. For example, a system may employ sixteen bit accuracy for a gray scale to allow for 2¹⁶, or 65, 536 different shades of gray. A color system may use sixteen bit accuracy for each of the RGB colors, allowing for 65,536 different shades each of red, green, and blue to be displayed. The desired level of pixel intensity accuracy can be dependent on a number of factors such as desired number of colors, size of color gamut, resolution of the display, and so forth. Having an increased pixel intensity accuracy enables the display to have a substantially continuous variation in intensity and/or color across the display. The substantially continuous variation limits perceived boundaries between similar areas and reduces anomalies such as banding.

For a sixteen bit system, the correction curve can be divided into 65,536 pixel correction values, with each correction value representing a correction for pixel intensity. The curve can then be divided into a predetermined number of evenly spaced interpolation segments. For example, the curve can be divided into 16 segments, though any number of segments may be used, depending on the desired accuracy. Each segment endpoint is assigned a value that is proportional or equal to an x axis value of a pixel correction value on the correction curve.

The correction curve representing 2^{N} pixel correction values can then be divided into 2^{p} additional segments, where p is an integer. In one example embodiment, p can be set equal to 1 to divide the correction curve in half. The number of segments in the half of the curve having the greater amount of curvature (greater amount of slope) can be increased by 2^{p} times, or 2 times in this example to provide for 16 segments. The 16 segment half of the correction curve can then be divided again and the number of segments in the half with the greatest amount of slope can again be multiplied by 2^{p} times. The division of the curve into 2^{p} pieces and multiplication of the segments by 2^{p} can be repeated until a desired level of accuracy is provided on the maximally curved section of the correction curve. In other words, the curve can be divided in this manner until the desired resolution is reached in the maximally curved section of the correction curve.

Following is an example interpolation table of a correction curve divided into seven levels with each level divided evenly into eight segments, with the final level having 16 segments. The hexadecimal values in this example are the values for the correction curve along the x axis (in hexadecimal) for the pixel correction value. The y axis value along the curve could then be determined based on the interpolated x axis value. The (decimal) number of pixel correction values between each segment is shown in the column on the right.

| | | | | | | | | | |
|---|---|---|---|---|---|---|---|---|---|
| 0000 | 0040 | 0080 | 00C0 | 0100 | 0140 | 0180 | 01C0 | Level | Δ 64 |
| | | | | | | | | 7 | |
| 0200 | 0240 | 0280 | 02C0 | 0300 | 0340 | 0380 | 03C0 | Level | Δ 64 |
| | | | | | | | | 7 | |
| 0400 | 0480 | 0500 | 0580 | 0600 | 0680 | 0700 | 0780 | Level | Δ 128 |
| | | | | | | | | 6 | |
| 0800 | 0900 | 0A00 | 0B00 | 0C00 | 0D00 | 0E00 | 0F00 | Level | Δ 256 |
| | | | | | | | | 5 | |
| 1000 | 1200 | 1400 | 1600 | 1800 | 1A00 | 1C00 | 1E00 | Level | Δ 512 |
| | | | | | | | | 4 | |
| 2000 | 2400 | 2800 | 2C00 | 3000 | 3400 | 3800 | 3C00 | Level | Δ 1024 |
| | | | | | | | | 3 | |
| 4000 | 4800 | 5000 | 5800 | 6000 | 6800 | 7000 | 7800 | Level | Δ 2048 |
| | | | | | | | | 2 | |
| 8000 | 9000 | A000 | B000 | C000 | D000 | E000 | F000 | Level | Δ 4096 |
| | | | | | | | | 1 | |

Thus, the eight interpolation points in Level 1 of this example each have 4096 pixel correction values between the interpolation segment endpoints. There are 2048 pixel correction values between each interpolation segment endpoint in Level 2, 1024 pixel correction values between endpoints in Level 3, and so forth, until Level 7, which represents the portion of the correction curve with the greatest amount of curvature. Level 7 includes 16 interpolation segment endpoints with only 64 pixel correction values between each endpoint.

FIG. 5 shows a correction curve divided into 7 levels as previously described. Level 1, encompassing the right half of the curve having the least amount of slope, includes half of the 65,536 pixel correction values. With eight interpolation segment endpoints within Level 1, there are 4096 pixel correction values between each segment endpoint. The next level contains half of the previous level, and so forth, until Level 7, which includes 16 interpolation segment endpoints divided among 1024 pixel correction values, or 64 values between each segment endpoint. It should be noted that Level 7, having a portion of the correction curve with the greatest amount of slope, has an exponentially greater amount of resolution than Level 1. Specifically, Level 7 has 64 values per segment endpoint while Level 1, having a portion of the correction curve with the smallest amount of slope, has 4096 pixel correction values between each segment endpoint. In other words, Level 7 has 26 times greater resolution than Level 1.

A correction value for any of the 65,536 pixel intensities can be determined using the interpolation table. For example, a correction value for pixel intensity 27,000 (hexadecimal 6,978) can be determined by interpolating in Level 2 between the 7000 segment endpoint and the 6800 segment endpoint. It can also be determined that pixel intensity 27,000 is 1,672 pixel intensities below the 7000 segment and 376 pixel intensities above the 6800 segment. This knowledge can be used to determine an offset value of the segment that will be interpolated to enable more accurate interpolation between the two segments to better determine a correction value using the interpolation table. This will be discussed more fully below.

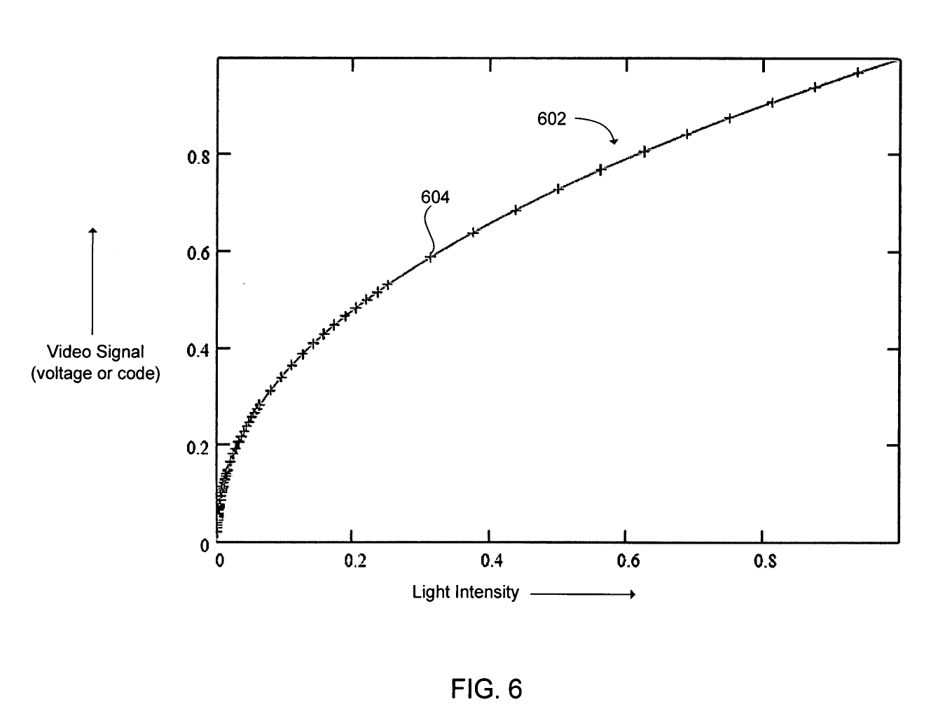

FIG. 6 shows a normalized plot of a transfer function correction curve 602 having a plurality of interpolation segment endpoints 604 distributed logarithmically along the curve. As previously discussed, the interpolation segment endpoints are evenly distributed among each of the seven logarithmically distributed levels, with each of the seven levels having half the width of the previous level. Of course, this is only one method for logarithmically distributing the interpolation segment endpoints. Other methods include logarithmically distributing each endpoint within each of the seven segments (instead of evenly distributing the endpoints within the levels), and logarithmically distributing the endpoints over the entire curve without breaking the curve into a plurality of levels. However, dividing the curve into levels provides certain advantages to implementing the interpolation in hardware and/or software, as will be discussed more fully below.

In one embodiment, a procedure has been devised for processing a pixel intensity input value to determine between which interpolation segment endpoints on a transfer function correction curve the pixel correction value is located and a proportion value that can be used to calculate the output value by interpolating between the endpoints. The process can be divided into five steps, as follows:
1) Determine the interpolation table level;
2) Shift the input value a level specific amount to determine the Level Offset and Proportion;
3) Determine the Level Base as a function of the interpolation table level from step 1;
4) Determine the interpolation segment address as a function of the Level Base from step 3 and the level offset from step 2; and
5) Complete the Interpolation.

The first step is to determine which level of the interpolation table is being used. For example, it must be determined in which of the seven levels of the curve shown in FIG. 5 that the pixel intensity will be located. This can be done in several different ways which include, but are not limited to: 1) using a table lookup, 2) counting leading non-significant zero bits, and 3) comparing input values to level boundary values (i.e. the values 0400, 0800, 1000, 2000, 4000, 8000 from the table above).

The second step is to process the input value in order to determine the proportion and level offset needed to complete the interpolation. This can be accomplished by shifting the input value left a level specific amount. In one embodiment, this can be accomplished by shifting a binary input value by an amount equal to the level (determined in step 1)−1 bits. So a pixel intensity that is determined to be in Level 4 of the curve would have its input value shifted to the left by 4−1 bits, or 3 bits. This operation does not discard any significant bits and it aligns the remaining significant bits so they can be divided into two fields referred to as the level offset field and the proportion field.

In the example embodiment above, the initial number space was divided into 16 interpolation segment endpoints, or 2⁴ segments. The four high bits can be used as the level offset value while the remaining lower order bits can be the proportion value. The proportion value, with a radix point assumed to be left of its high order bit, is one of the values that can be used to determine the interpolation amount.

The third step is to determine the Level Base value. Note that in the example above the interpolation table was divided into seven levels. An index to the interpolation table can be calculated as the level base plus the level offset, or (((Total number of Levels−Selected Level)*8)+level offset). As such, the Level Base is represented by the equation ((Total number of Levels−Selected Level)*8). Since the level base resolves to a constant value proportional to one of the number of levels, the Level Base value can be implemented by using the Level (the signal from step 1) to select the appropriate constant.

The fourth step is to determine the interpolation table segment entry by adding the Level Offset from step two and the Level Base from step 3.

The fifth step is to complete the interpolation by multiplying the proportion from step two by the segment offset value and then adding the result to the segment base value to form the output value. The segment offset and segment base values for this step are retrieved from the interpolation table based on the segment entry determined in step four.

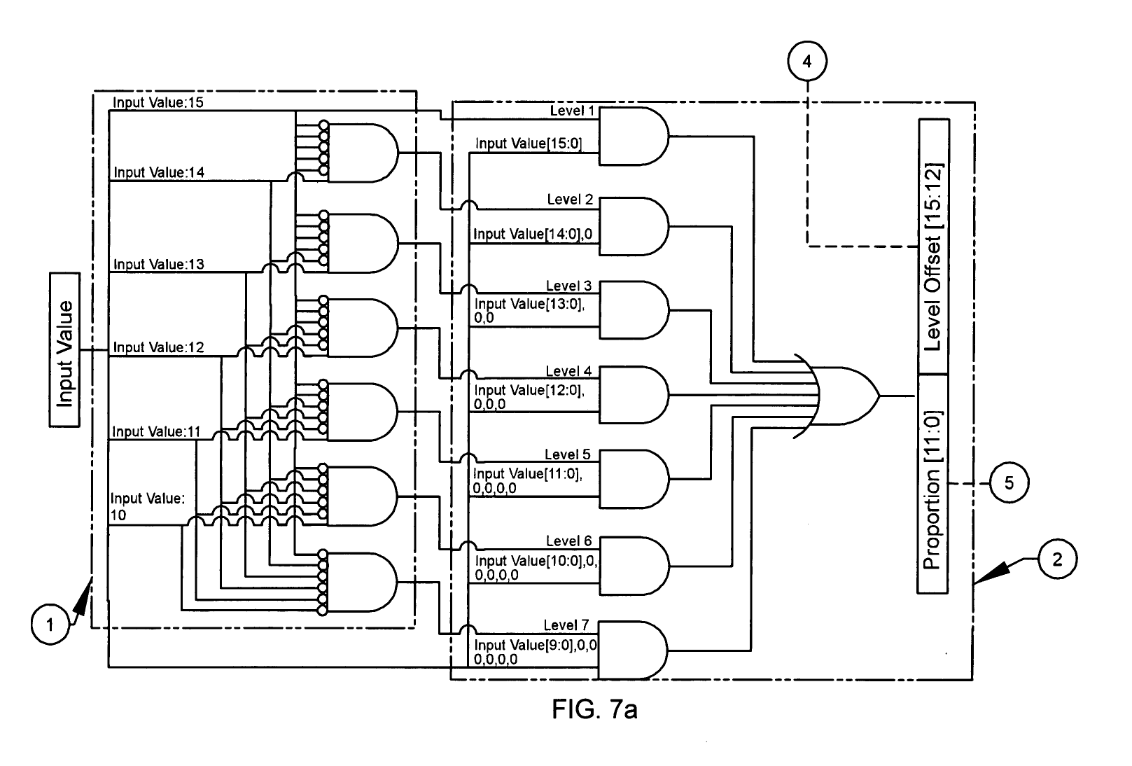

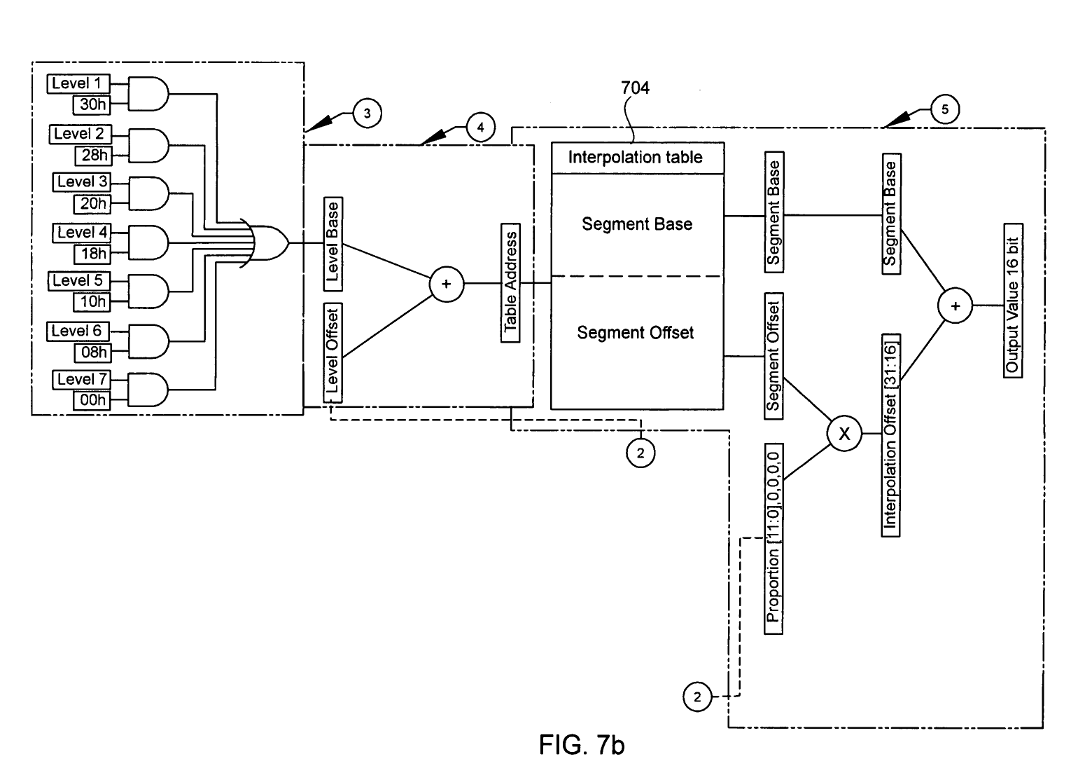

FIGS. 7a and 7b are a diagram of one possible implementation of a system for correcting pixel intensities for output on a video display that involves logarithmically distributing interpolation table endpoints along a transfer function correction curve. The diagram is divided into 5 blocks over FIGS. 7a and 7b.

In block 1 in FIG. 7a, an input value can be received. The input value can be configured to enable a pixel correction value to be determined along the transfer function correction curve for any of 2ⁿ pixel intensities. The input value can be a 16 bit value in this example, though any resolution sufficient to obtain desired results interpolating along the transfer function curve can be used. In one example embodiment, the input value can be 5,615 in decimal or 15ef in hex (15efh). Translated to binary, this value is 0001 0101 1110 1111. Bits 15-13 are zero and bit 12 is a one. Translating the logic shown in block 1, it can be seen that Level 4 will be true and all other levels will be false.

As previously stated in step two above, the input value is shifted to the left by an amount equal to the level−1 bits, or 4−1=3 bits. This gives a value of 1010 1111 0111 1000. In block 2 in FIG. 7a the input value is then separated into a level offset value comprising bits 12-15 and a proportion value comprising bits 0-11. The 12 bit proportion value is then shifted to the left and padded by 4 zeros to form a proportion value of 1111 0111 1000 000 (0f780h) and a Level Offset value of 1010 (0ah).

In block 3, as shown in FIG. 7b, it is known that Level 4 has been selected. The Level 4 signal is again used to select one of seven constants which represent the value which would be computed by the equation ((Total number of Levels−Selected Level)*8). In this example, there are 7 total levels and level 4 has been selected, so the output is 24 decimal, or 18 hex. Therefore, Level Base becomes 18h when Level 4 is true.

In block 4, as shown in FIG. 7b the Level Offset value (0ah) from block 2 in FIG. 7a is then added to the Level Base value (18h) to produce the interpolation table address of 22 hex or 34 decimal.

In block 5, as shown in FIG. 7b, the interpolation table address is used to locate an entry in the interpolation table 704 having logarithmically distributed entries. For example, as previously shown in the table above, and in FIG. 6, the interpolation table can include logarithmically distributed entries representing the interpolation segment endpoints. As in the previously presented example, with 6 levels having 8 segments each, and a seventh level having 16 segments, the table can include 64 entries, with each entry representing a logarithmically distributed segment endpoint, referred to as the Segment Base. Each of the entries can have 16 bits of precision in this example. The actual level of precision can vary from 8 bits to 64 bits, depending on a number of factors as previously discussed. A second section in the interpolation table can include a Segment Offset value, representing a width of each segment base, or the distance between two segment endpoints. The second section can comprise 64 Segment Offset values, with each segment offset value having 16 bits of precision. The Segment Offset values can have the same precision as the Segment base values or a different level of precision. The segment base and associated segment offset values can be accessed using the interpolation table address determined in block 4.

For example, entry 34 in the interpolation lookup table, determined in block 4, may have a Segment Offset value of 2d0h and a Segment Base value of 7b4eh. Interpolation continues by computing the Interpolation Offset value as the Proportion value (0f780h) times the Segment Offset value (2d0h). The result is a 32 bit number. The 16 most significant bits can be selected, in this embodiment, as the Interpolation Offset value of 0000 0010 1011 1000, or 2b8h. The interpolation offset value (2b8h) can then be added to the Segment Base (7b4eh) to produce the resulting interpolation output value of 7e06h (32,262 decimal) on the transfer function correction curve. The pixel correction value can then be applied to the pixel intensity to produce a desired intensity on a display.

The implementation of a system for correcting pixel intensities shown in FIGS. 7a and 7b represents a viable system having sufficient speed that it can be used for real time correction of high resolution video signals. The system is also simple enough that it can be implemented cost effectively in a complex video display device.

For example, a grating light valve (GLV) type display can be used to achieve a video display having a tremendous level of resolution of 32 megapixels or more. The GLV produces images using thousands of ribbons, with each ribbon representing a row in a display. A high end GLV display may include over 4,000 ribbons. Each ribbon can require a separate transfer function to correct for nonlinearities specific to that ribbon in the display system. A transfer function correction system, as shown in FIGS. 7a and 7b, can be implemented in a cost effective manner for each of the ribbons in a GLV. The system(s) and method(s) disclosed enable compensation for nonlinearities in pixel intensity for display devices having relatively high intensity step size resolution. The system can be implemented in any type of display that requires near-real-time correction for non-linear displays used to display high resolution images having high resolution color displays, such as 30, 36, 48 bit or even greater resolution color images.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

1. A method for correcting pixel intensities for output on a video display, comprising:
generating an interpolation table having a plurality of interpolation segment endpoints spaced over a transfer function correction curve;
distributing the plurality of interpolation segment end points logarithmically over the correction transfer function curve to enable a higher resolution on a first portion of the correction transfer function curve having a greater amount of slope relative to a second portion of the correction transfer function curve having a smaller amount of slope; and
determining correction values for a graphic display by interpolating between the logarithmically distributed interpolation segment endpoints.

2. A method as in claim 1, wherein generating an interpolation table further comprises generating an interpolation table having a plurality of interpolation segment endpoints spaced over a transfer function correction curve, wherein the correction transfer function curve comprises 2ⁿ pixel intensity correction values, wherein n is a number of bits of precision of a pixel intensity value.

3. A method as in claim 2, further comprising defining a transfer function correction curve having 2ⁿ pixel intensity correction values, wherein n is greater than 8.

4. A method as in claim 2, further comprising dividing the transfer function correction curve into 2^{p} levels, where p is an integer.

5. A method as in claim 4, further comprising increasing a number of interpolation segment end points in each new level by 2^{p} times.

6. A method as in claim 5, further comprising dividing each new level into 2^{p} levels and increasing the number of interpolation segment end points in each new level by 2^{p} times until a desired number of interpolation segment end points are distributed along the transfer function correction curve.

7. A method as in claim 1, wherein distributing the plurality of interpolation segment end points further comprises distributing the plurality of interpolation segment endpoints evenly in each of a plurality of logarithmically distributed levels, wherein each level represents a portion of the transfer function correction curve.

8. A method as in claim 1, wherein interpolating between the segments further comprises interpolating between the segments based on an offset value and a proportion value.

9. A method as in claim 8, wherein the step of generating an interpolation table further comprises generating an interpolation table comprised of a plurality of logarithmically distributed interpolation segment endpoints and a plurality of segment offset values corresponding to each interpolation segment endpoint.

10. A method as in claim 1, wherein determining correction values for a graphic display further comprises determining correction values for a plurality of colors in a graphic display by interpolating between the logarithmically distributed interpolation segment endpoints for each of the plurality of colors.

11. A method as in claim 10, further comprising determining transfer function correction values for a plurality of colors, wherein the colors are selected from the group consisting of red, green, blue, cyan, magenta, yellow, and black.

12. A method as in claim 1, wherein distributing the plurality of interpolation segment end points logarithmically further comprises distributing the plurality of interpolation segment end points logarithmically over the correction transfer function curve to enable an exponentially higher resolution on a first portion of the correction transfer function curve having a greater amount of slope relative to a second portion of the correction transfer function curve having a smaller amount of slope.

13. A system for correcting pixel intensities for output on a video display, comprising
a computer memory device configured to store an interpolation table with logarithmically distributed entries;
an input value configured to represent a pixel intensity on the video display;
wherein the input value includes a level value that represents a selected level of a correction transfer function curve;
wherein the input value further includes a level offset value that represents a segment of the level of the correction transfer function curve;
wherein the input value further includes a proportion value configured to represent a proportional distance along the segment;
a computer processing device configured to access the interpolation table in the computer memory device and access one or more inputs within the interpolation table based on a table address of the interpolation table to determine a specific segment base value and a segment offset value;
the computer processing device further configured to multiply the proportion value by the segment offset value to determine an interpolation offset value; and
the computer processing device further configured to add the interpolation offset value with the segment base value to determine an output value, wherein the output value represents a corrected pixel intensity value.

14. A means for correcting pixel intensities for output on a video display, comprising:
a means for generating an interpolation table having a plurality of interpolation segment endpoints spaced over the input values;
a means for distributing the plurality of interpolation segment end points logarithmically to enable an exponentially higher resolution in a portion of the interpolation table related to a first portion of a correction transfer function curve having a greater amount of slope relative to a second portion of the correction transfer function curve having a smaller amount of slope; and
a means for determining correction values for a graphic display by interpolating between the logarithmically distributed interpolation segment endpoints.

15. A method for correcting pixel intensities for output on a video display using an interpolation table, comprising:
dividing the interpolation table into a plurality of table levels, wherein each succeeding table level is 1/2^{p} times a size of a preceding table level;
separating each table level into a plurality of segments comprising interpolation segment endpoints;
interpolating between the interpolation segment endpoints to determine a pixel intensity correction value for a predetermined pixel intensity level.

16. A method as in claim 15, wherein interpolating between the interpolation segment endpoints further comprises determining which of the table levels is represented in an input value.

17. A method as in claim 16, wherein interpolating between the interpolation segment endpoints further comprises shifting the input value a level specific amount to determine a level offset value and a proportion value.

18. A method as in claim 17, wherein interpolating between the interpolation segment endpoints further comprises calculating a level base value as a function of the table level.

19. A method as in claim 18, wherein interpolating between the interpolation segment endpoints further comprises determining an interpolation segment address of the interpolation table, wherein the address is a function of the level base value and the level offset value.

20. A method as in claim 19, wherein interpolating between the interpolation segment endpoints further comprises accessing the address to retrieve a segment base value and a segment offset value.

21. A method as in claim 20, wherein interpolating between the interpolation segment endpoints further comprises calculating a pixel intensity output value by multiplying the proportion value by the segment offset value to form an interpolation offset value and adding the interpolation offset value to the segment base value to form the pixel intensity output value.
